(19) United States
(12) Patent Application Publication
(10) Pub. No.: US 2024/0090219 A1
(43) Pub. Date: Mar. 14, 2024

(54) VERTICAL MEMORY DEVICE

(71) Applicant: SAMSUNG ELECTRONICS CO., LTD., Suwon-si (KR)

(72) Inventors: Jongseon AHN, Suwon-si (KR); Seungyoon Kim, Suwon-si (KR); Heesuk Kim, Suwon-si (KR); Yejin Park, Suwon-si (KR); Jaehwang Sim, Suwon-si (KR)

(21) Appl. No.: 18/231,284

(22) Filed: Aug. 8, 2023

(30) Foreign Application Priority Data
Sep. 8, 2022 (KR) 10-2022-0114413

(51) Int. Cl. H10B 43/27; H10B 41/27; H10B 41/35; H10B 41/41; H10B 43/35; H10B 43/40

(52) U.S. Cl. CPC H10B 43/27; H10B 41/27; H10B 41/35; H10B 41/41; H10B 43/35; H10B 43/40

(57) ABSTRACT

A vertical memory device includes: a lower pad pattern disposed on a substrate; a cell stack structure disposed on the lower pad pattern and including first insulation layers and gate patterns, wherein the cell stack structure has a stepped shape; a through cell contact including a first through portion and a first protrusion, wherein the first through portion passes through a portion of the cell stack structure, and wherein the first protrusion protrudes from the first through portion and contacts an uppermost gate pattern of the gate patterns; and a first insulation pattern at least partially surrounding a sidewall, of the first through portion, that is below the first protrusion, wherein the first insulation pattern is longer than the first protrusion in a horizontal direction from the first through portion, and wherein a vertical thickness of the first protrusion is greater than a vertical thickness of the uppermost gate pattern.

### CROSS-REFERENCE TO RELATED APPLICATION

This application claims priority under 35 USC § 119 to Korean Patent Application No. 10-2022-0114413, filed on Sep. 8, 2022, in the Korean Intellectual Property Office (KIPO), the disclosure of which is incorporated by reference herein in its entirety.

### TECHNICAL FIELD

Example embodiments of the present inventive concept relate to a vertical memory device.

### DISCUSSION OF THE RELATED ART

Currently, a vertical memory device having a structure in which memory cells are vertically stacked has been under development. The vertical memory device may typically include wirings electrically connected to memory cells that are formed on each layer in the vertical memory device.

### SUMMARY

According to an example embodiment of the present inventive concept, a vertical memory device includes: a lower pad pattern disposed on a substrate; a cell stack structure disposed on the lower pad pattern, wherein the cell stack structure includes first insulation layers and gate patterns alternately and repeatedly stacked, wherein the cell stack structure extends in a first direction parallel to an upper surface of the substrate, and has a stepped shape; a through cell contact including a first through portion and a first protrusion, wherein the first through portion extends in a vertical direction and passes through a portion of the cell stack structure having the stepped shape, and wherein the first protrusion protrudes from the first through portion and contacts a sidewall of an uppermost gate pattern, of the gate patterns, that is adjacent to the first through portion; and a first insulation pattern at least partially surrounding a sidewall, of the first through portion, that is positioned below the first protrusion, wherein the first insulation pattern is longer than the first protrusion in a horizontal direction from the first through portion, and wherein a vertical thickness of the first protrusion of the through cell contact is greater than a vertical thickness of the uppermost gate pattern that contacts the first protrusion.

According to an example embodiment of the present inventive concept, a vertical memory device includes: lower circuit patterns disposed on a substrate; a lower pad pattern electrically connected to the lower circuit patterns; a base pattern disposed on the lower pad pattern; a cell stack structure disposed on the base pattern, wherein the cell stack structure includes first insulation layers and gate patterns alternately and repeatedly stacked, wherein the cell stack structure extends in a first direction parallel to an upper surface of the substrate, and having a stepped shape; a channel structure extending to the base pattern and passing through the cell stack structure; an insulating interlayer covering the cell stack structure; a through cell contact including a first through portion and a first protrusion, wherein the first through portion extends in a vertical direction to the lower pad pattern and passes through the insulating interlayer and a portion having the stepped shape in the cell stack structure, and wherein the first protrusion protrudes from the first through portion and contacts a sidewall of an uppermost gate pattern, of the gate patterns, that is adjacent to the first through portion; and a first insulation pattern at least partially surrounding a sidewall, of the first through portion, that is positioned below the first protrusion, wherein the first insulation pattern has a length in the first direction that is greater than a length, in the first direction, of the first protrusion from the first through portion, and wherein a horizontal distance between a contacting portion that is between the first protrusion and the uppermost gate pattern and a contacting portion that is between the first insulation pattern and a gate pattern, of the gate patterns, that is disposed below the uppermost gate pattern is about 15 nm or more.

According to an example embodiment of the present inventive concept, a vertical memory device includes: a cell stack structure disposed on a substrate, wherein the cell stack structure includes first insulation layers and gate patterns alternately and repeatedly stacked, wherein the cell stack structure has a stepped shape at an edge thereof, and wherein a thickness of an uppermost gate pattern, of the gate patterns, that is exposed at the edge is greater than that of the gate pattern, of the gate patterns, that is disposed below the uppermost gate pattern; a through cell contact including a first through portion and a first protrusion, wherein the first through portion extends in a vertical direction and passes through the cell stack structure, and wherein the first protrusion protrudes from the first through portion and contacts a sidewall of the uppermost gate pattern that is adjacent to the first through portion; and a first insulation pattern at least partially surrounding a sidewall, of the first through portion, that is positioned below the first protrusion, wherein the first insulation pattern contacts a sidewall of the gate pattern that is disposed below the uppermost gate pattern, and wherein a horizontal distance between a contacting portion that is between the first protrusion and the uppermost gate pattern and a contacting portion that is between the first insulation pattern and the gate pattern that is disposed below the uppermost gate pattern is about 15 nm or more.

### BRIEF DESCRIPTION OF THE DRAWINGS

The above and other features of the present inventive concept will become more apparent by describing in detail example embodiments thereof, with reference to the accompanying drawings, in which:

FIGS. 1, 2, 3, 4, 5, 6, 7, 8, 9, 10, 11, 12, 13, 14, 15, 16, 17, 18, 19, 20, 21, 22, 23 and 24 are cross-sectional views illustrating a method of manufacturing a vertical memory device according to an example embodiment of the present inventive concept.

FIG. 25 is a schematic diagram illustrating an electronic system including a semiconductor device according to an example embodiment of the present inventive concept.

FIG. 26 is a schematic perspective view of an electronic system including a semiconductor device according to an example embodiment of the present inventive concept.

FIG. 27 is a schematic cross-sectional view illustrating a semiconductor package including a semiconductor device according to an example embodiment of the present inventive concept.

### DETAILED DESCRIPTION OF THE EMBODIMENTS

Hereinafter, embodiments of the present inventive concept will be described in detail with reference to the accompanying drawings.

Hereinafter, two directions substantially parallel to an upper surface of a substrate and substantially perpendicular to each other may be defined as a first direction and a second direction, respectively, and a direction substantially perpendicular to the upper surface of the substrate may be defined as a vertical direction (or, e.g., a third direction).

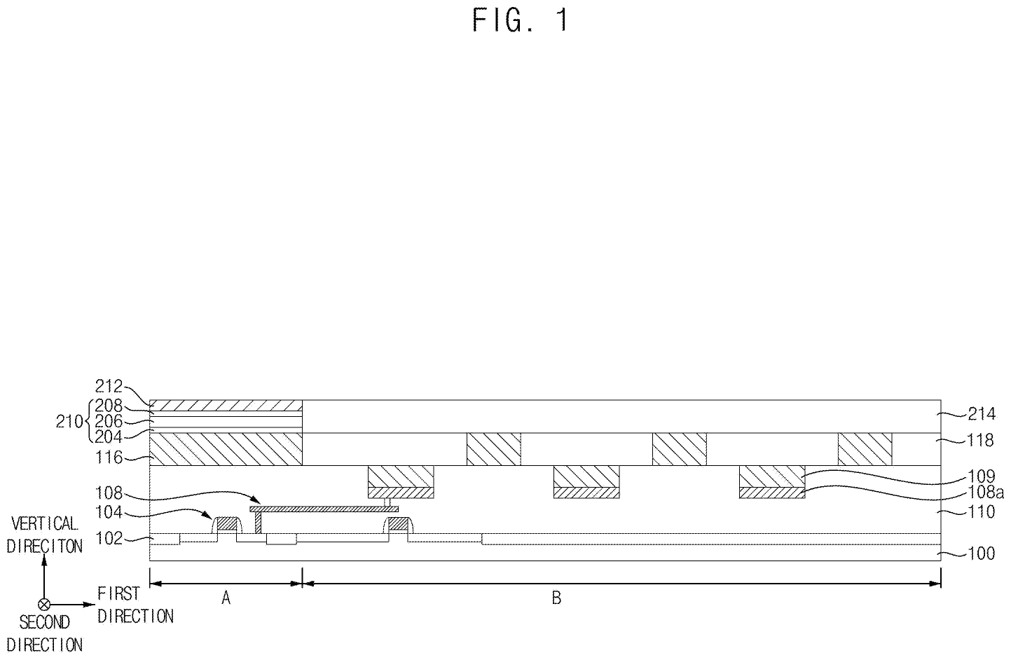

FIGS. 1 to 24 are cross-sectional views illustrating a method of manufacturing a vertical memory device according to an example embodiment of the present inventive concept.

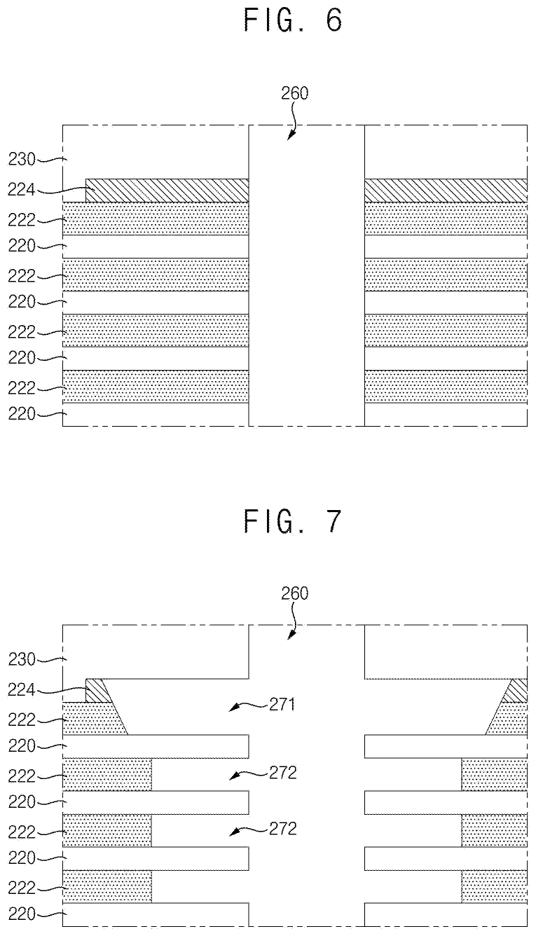

FIGS. 1 to 5, 10, 19, 22 and 24 are cross-sectional views of the vertical memory device cut in a first direction. FIGS. 6 to 9, 11 to 18, 20, 21, and 23 are enlarged cross-sectional views of portions of the vertical memory device.

Referring to FIG. 1, circuit patterns constituting a peripheral circuit may be formed on a substrate 100, and a lower insulating interlayer 110 may be formed to cover the circuit patterns.

The substrate 100 may include a first region A, where a memory cell array is formed, and a second region B extending from the memory cell array. The second region B may be a region for forming contacts (e.g., electrical connections) and wirings electrically connected to gate patterns. The first and second regions A and B may include an upper surface of the substrate 100 and regions extending in the vertical direction from the upper surface of the substrate 100.

A shallow trench isolation process may be performed on the substrate 100 to form an isolation pattern 102. Accordingly, the substrate 100 may be divided into a field region in which the isolation pattern 102 is formed and an active region in which the isolation pattern 102 is not formed. Lower transistors 104 and lower wirings 108 may be formed on the substrate 100. The lower transistors 104 and the lower wirings 108 may serve as the circuit patterns constituting the peripheral circuit.

Some of the lower wirings 108 may serve as lower pad patterns 108a to be connected to contact plugs subsequently formed. A protective pattern 109 may be formed on the lower pad pattern 108a. The protective pattern 109 may protect the lower pad pattern 108a, during performance of subsequent processes. The protective pattern 109 may include, e.g., polysilicon.

A base pattern 116 may be formed on the lower insulating interlayer 110 in the first region A. In the second region B, a plurality of base patterns 116 may be formed on the lower insulating interlayer 110, and the base patterns 116 may be spaced apart from each other. A base insulation layer 118 may be formed between the base patterns 116 in the second region B. A portion of the second region B where the base insulation layer 118 is formed may correspond to a portion for forming a through cell contact.

The base pattern 116 may include, e.g., polysilicon or single crystal silicon. The base insulation layer 118 may include, e.g., silicon oxide.

A lower sacrificial layer structure 210 and a support layer pattern 212 may be formed on the base pattern 116 in the first region A. A lower insulation layer pattern 214 may be formed on the base pattern 116 and the base insulation layer 118 in the second region B. In example embodiments of the present inventive concept, an upper surface of the support layer pattern 212 and an upper surface of the lower insulation layer pattern 214 may be substantially coplanar with each other.

The lower sacrificial layer structure 210 may include first, second and third lower sacrificial layers 204, 206 and 208 sequentially stacked on the base pattern 116. In this case, the first and third lower sacrificial layers 204 and 208 may include, e.g., an oxide such as silicon oxide, and the second lower sacrificial layer 206 may include, e.g., a nitride such as silicon nitride. The support layer pattern 212 may be formed of a material having an etch selectivity with respect to the first to third lower sacrificial layers 204, 206 and 208. The support layer pattern 212 may include e.g., undoped polysilicon or polysilicon doped with n-type impurities. In some example embodiments of the present inventive concept, a portion of the support layer pattern 212 may pass through the lower sacrificial layer structure 210, and may contact the upper surface of the base pattern 116.

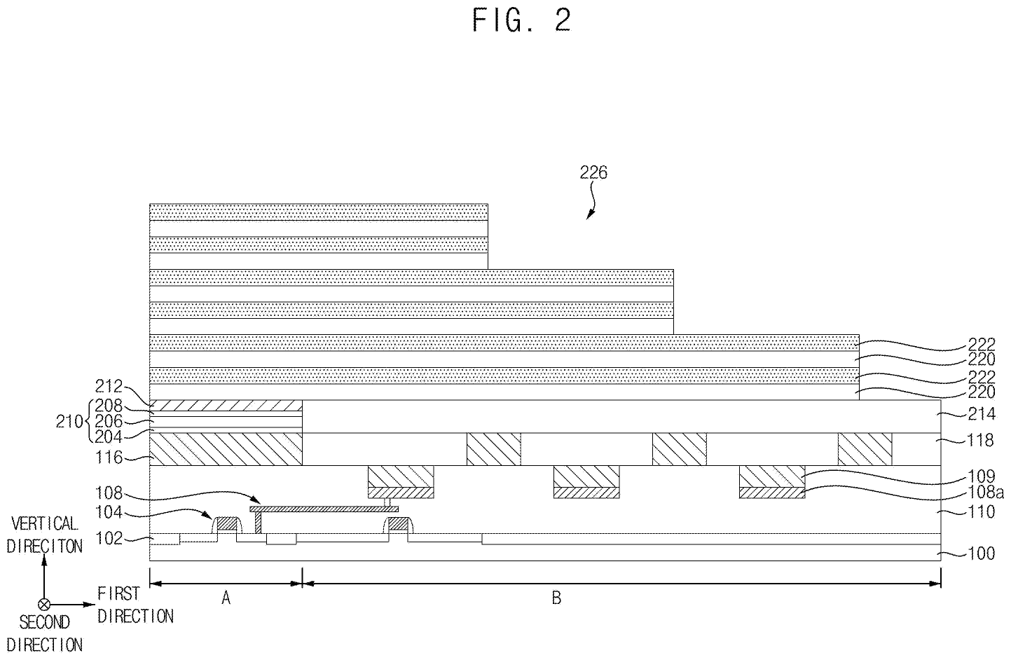

Referring to FIG. 2, first insulation layers 220 and first sacrificial layers 222 may be alternately and repeatedly stacked on the support layer pattern 212 and the lower insulation layer pattern 214. The first insulation layer 220 may include, e.g., silicon oxide. The first sacrificial layer 222 may include a material having an etch selectivity with respect to the first insulation layer 220. The first sacrificial layer 222 may include, e.g., a nitride such as silicon nitride. FIG. 2 shows six first sacrificial layers 222 that are stacked. However, the number of the first sacrificial layers 222 might not be limited thereto. For example, there may be more or less than six layers of the first sacrificial layers 222.

Thereafter, the first insulation layers 220 and the first sacrificial layers 222 may be patterned to form a first preliminary mold structure 226 on the support layer pattern 212 and the lower insulation layer pattern 214. The first preliminary mold structure 226 may have a stepped shape in the second region B.

Hereinafter, in each structure, a portion having a stepped shape in the second region B may be referred to as a step portion. A step may be defined as an exposed portion of the step portion that is not covered by an upper layer, and the step of one layer may include an upper surface of the step and a vertical sidewall connected to the upper surface and extending downward.

In some example embodiments of the present inventive concept, an edge portion of the first preliminary mold structure 226 in the first direction may include steps in the first direction and the second direction, respectively. In some example embodiments of the present inventive concept, the edge portion of the first preliminary mold structure 226 in the first direction may include steps only in the first direction. Hereinafter, an example, in which the first preliminary mold structure 226 has steps of three layers in the first direction and steps of two layers in the second direction, may be described.

The first sacrificial layer 222 may be exposed at an upper surface of each of steps. One or a plurality of first insulation layers 220 and one or a plurality of first sacrificial layers 222 may be exposed at a vertical sidewall of each of steps.

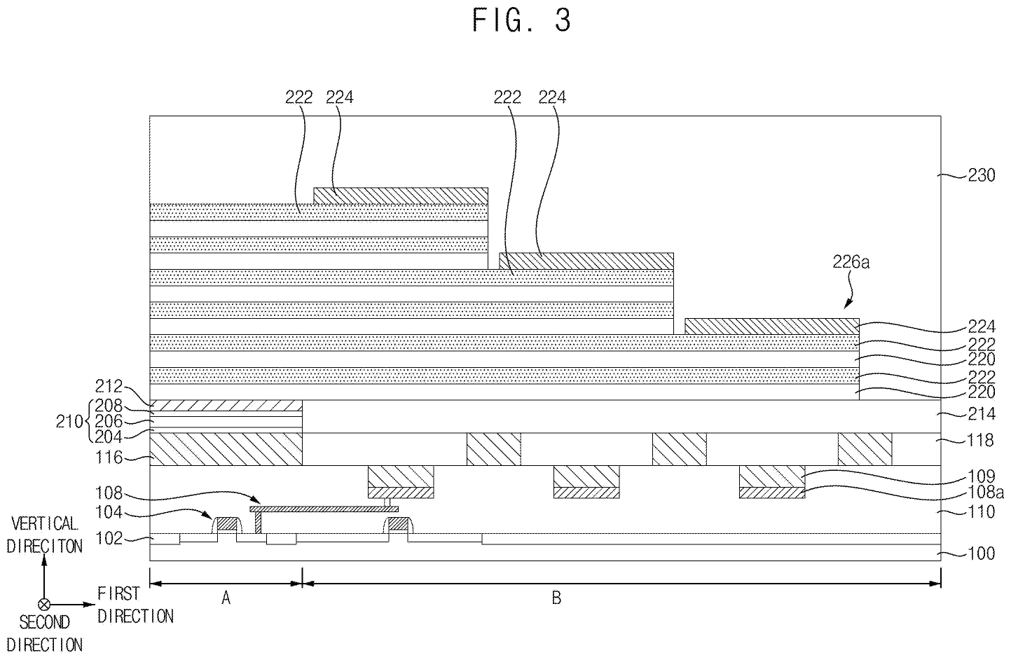

Referring to FIG. 3, a second sacrificial layer pattern 224 may be formed on the upper surface of each of the steps of the first preliminary mold structure 226 in the second region B. The first preliminary mold structure 226 and the second sacrificial layer pattern 224 may form a second preliminary mold structure 226a. The second sacrificial layer pattern 224 might not contact the first sacrificial layer 222 disposed on the step up one layer. The second sacrificial layer pattern 224 might not be formed on a sidewall of each of the steps, and may be spaced apart from the sidewall of each of the steps.

The second sacrificial layer pattern 224 may include a material having an etching rate higher than an etching rate of the first sacrificial layer 222 in the same etching process. In some example embodiments of the present inventive concept, the second sacrificial layer pattern 224 may include the same element as that of the first sacrificial layer 222. For example, the second sacrificial layer pattern 224 may include silicon nitride. In some example embodiments of the present inventive concept, the second sacrificial layer pattern 224 may include a material different from that of the first sacrificial layer 222. For example, the second sacrificial layer pattern 224 may include polysilicon.

An insulation layer may be formed to cover the second preliminary mold structure 226a. An upper surface of the insulation layer may be planarized to form a first insulating interlayer 230. The first insulating interlayer 230 may include, e.g., silicon oxide.

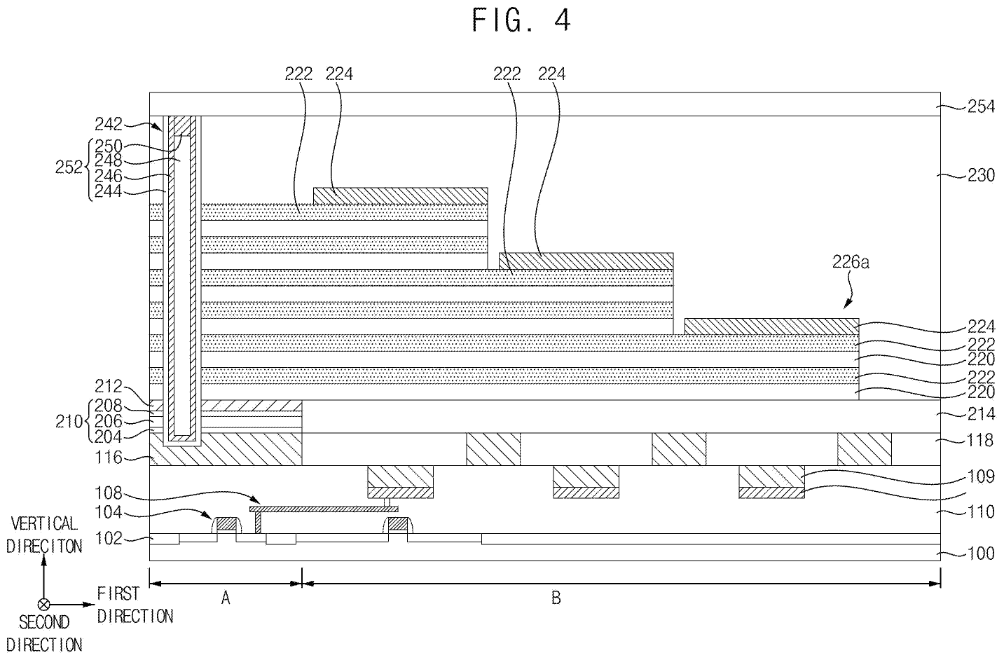

Referring to FIG. 4, channel holes 242 may be formed through the second preliminary mold structure 226a in the first region A. The channel holes 242 may extend to an upper portion of the base pattern 116. To avoid complicating the drawing, only one channel hole may be shown in FIG. 4, as an example.

A preliminary channel structure 252 may be formed in each of the channel holes 242. In some example embodiments of the present inventive concept, the preliminary channel structure 252 may include a preliminary charge storage structure 244, a channel 246, a filling insulation pattern 248, and a capping pattern 250. The preliminary charge storage structure 244 may include a preliminary first blocking layer, a preliminary charge storage layer, and a preliminary tunnel insulation layer sequentially stacked on a sidewall of the channel hole 242.

A second insulating interlayer 254 may be formed on the first insulating interlayer 230 and the preliminary channel structure 252.

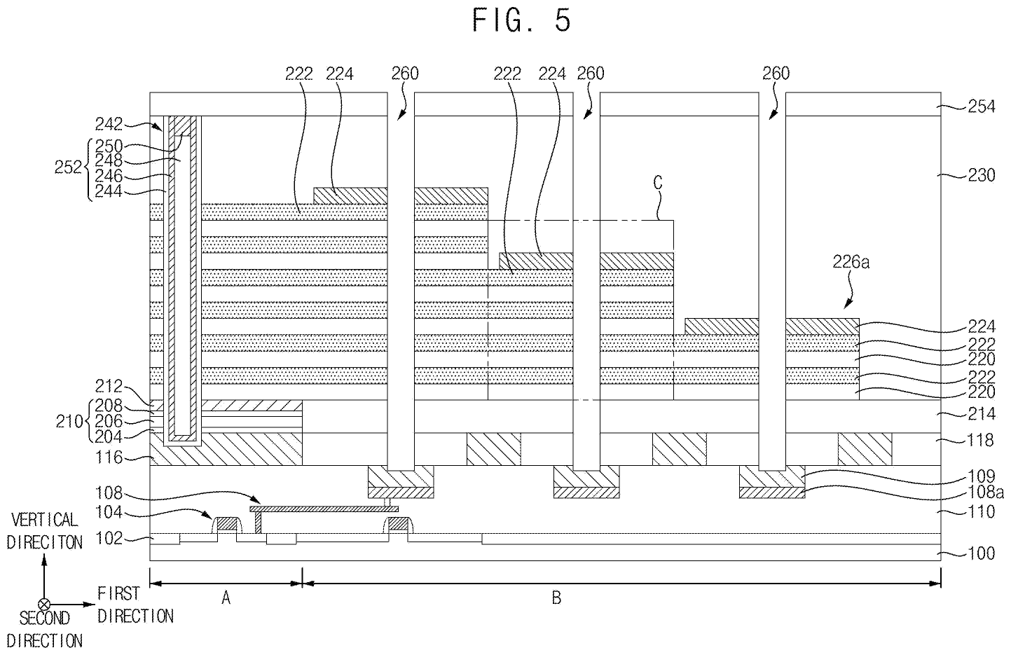

FIGS. 6 to 9 and FIGS. 11 to 18, 20, 21, and 23 are enlarged views of a portion C of FIG. 5.

Referring to FIGS. 5 and 6, first holes 260 may be formed through the first and second insulating interlayers 230 and 254 and the step portion of the second preliminary mold structure 226a. Each of the first holes 260 may pass through a corresponding step of the steps of the step portion. The first holes 260 may be formed as through cell contacts by subsequent processes. The first hole 260 may pass through the first and second insulating interlayers 230 and 254, the second preliminary mold structure 226a, the lower insulation layer pattern 214 and the base insulation layer 118, and the first hole 260 may extend to an upper portion of the protective pattern 109. Therefore, the protective pattern 109 may be exposed by a bottom of the first hole 260.

Referring to FIG. 7, the first sacrificial layers 222 and the second sacrificial layer pattern 224, which are exposed by a sidewall of each of the first holes 260, may be partially removed to form a first recess 271 and second recesses 272. Each of the first and second recesses 271 and 272 may be communicated (or, e.g., connected) with the sidewall of the first hole 260. The removing process may include, e.g., a wet etching process.

A stack structure of the first sacrificial layer 222 and the second sacrificial layer pattern 224, which are in a top of the second preliminary mold structure 226a and are exposed by the sidewall of the first hole 260, may be partially etched to form the first recess 271. Portions of the first sacrificial layers 222 positioned below the first recess 271 may be etched to form the second recesses 272.

The top of the second preliminary mold structure 226a, which is exposed by the sidewalls of the first holes 260, may include the stacked structure including the first sacrificial layer 222 and the second sacrificial layer pattern 224, so that a thickness of the stacked structure of the top of the second preliminary mold structure 226a may be relatively thicker than each of the first sacrificial layers 222 below the stacked structure. Since the second sacrificial layer pattern 224 is etched faster than the first sacrificial layer 222 in the removing process, the stacked structure including the first sacrificial layer 222 and the second sacrificial layer pattern 224 may be etched faster than the first sacrificial layers 222 thereunder. Therefore, the first recess 271 may have a width in a horizontal direction (e.g., a lateral direction) greater than a width in the horizontal direction of each of the second recesses 272. In addition, the first recess 271 may have a vertical height greater than a vertical height of each of the second recesses 272.

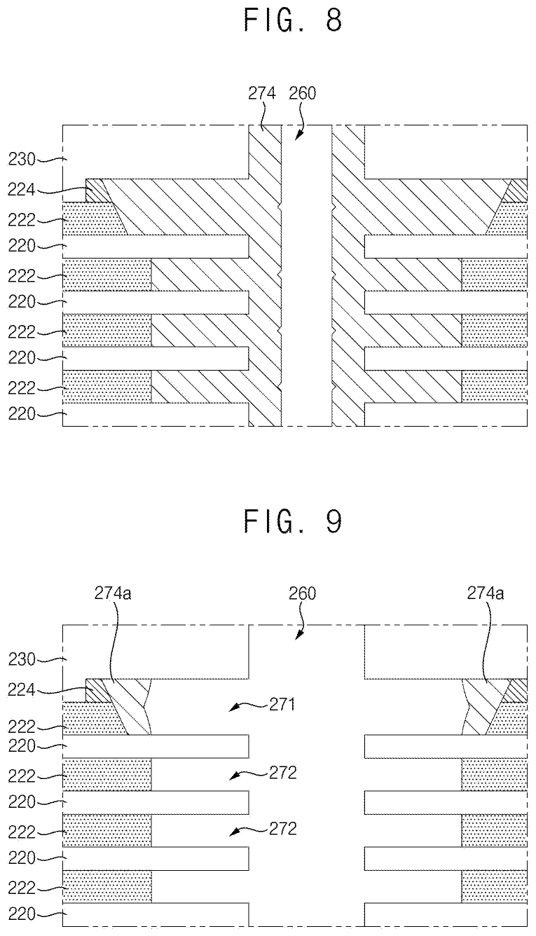

Referring to FIG. 8, a third sacrificial layer 274 may be conformally formed along an upper surface of the second insulating interlayer 254, surfaces of the first holes 260, and surfaces of the first and second recesses 271 and 272. The third sacrificial layer 274 may fill the first and second recesses 271 and 272. For example, the third sacrificial layer 274 may completely fill the first and second recesses 271 and 272. However, the third sacrificial layer 274 may be formed along surfaces of the first holes 260 without completely filling the first holes 260.

The third sacrificial layer 274 may include a material including elements the same as elements of the first sacrificial layer 222 and the second sacrificial layer pattern 224. The third sacrificial layer 274 may include, e.g., silicon nitride. In some example embodiments of the present inventive concept, the third sacrificial layer 274 may be formed by a low-pressure chemical vapor deposition process.

Referring to FIG. 9, the third sacrificial layer 274 may be partially removed to form a third sacrificial layer pattern 274a in the first recess 271.

In the removing process, the third sacrificial layer 274 formed on the surface of the first hole 260 and filling the second recess 272 may be removed. Thus, a sidewall of the first sacrificial layer 222 may be exposed by the second recess 272. In addition, a portion of the third sacrificial layer 274 in the first recess 271 may be partially removed to form a third sacrificial layer pattern 274a on sidewalls of the first sacrificial layer 222 and the second sacrificial layer pattern 224 in the first recess 271. The removing process may include, e.g., a wet etching process.

After performing the etching process, an inner width of the first recess 271 in the horizontal direction may be substantially the same as or similar to an inner width of the second recess 272 in the horizontal direction.

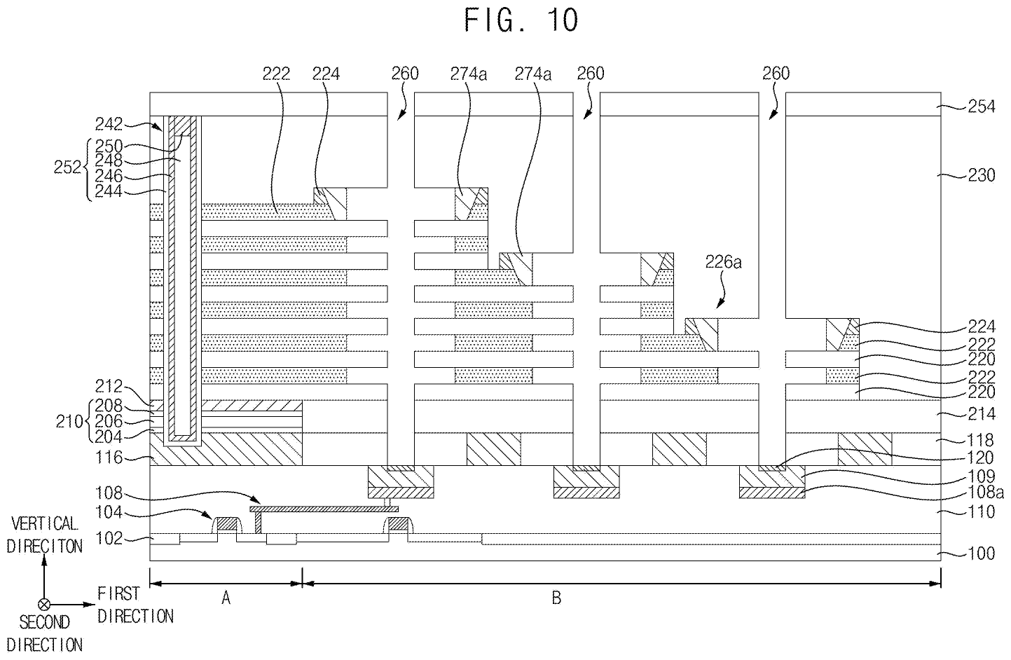

Referring to FIG. 10, the surface of the protective pattern 109, which is exposed by the bottom of the first hole 260, may be oxidized to form an oxide layer pattern 120 on the protective pattern 109. The oxide layer pattern 120 may serve as an etch stop pattern to prevent from removing of the protective pattern 109 or damaged the protective pattern 109 in subsequent processes. The oxidation process may include, e.g., thermal oxidation or radical oxidation.

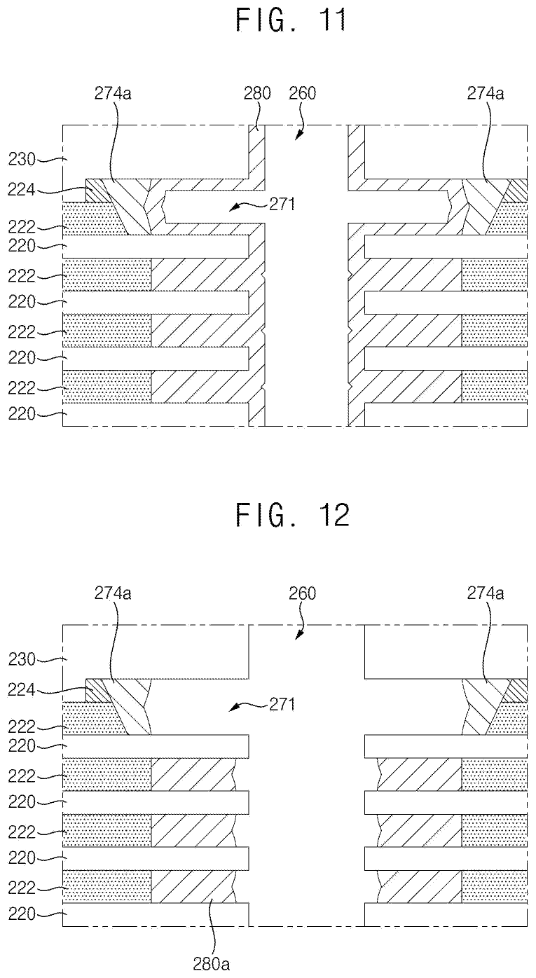

Referring to FIG. 11, a fourth sacrificial layer 280 may be conformally formed along the upper surface of the second insulating interlayer 254, the surfaces of the first holes 260, and the surfaces of the first and second recesses 271 and 272.

The fourth sacrificial layer 280 may be formed to fill each of the second recesses 272. For example, the fourth sacrificial layer 280 may be formed to completely fill each of the second recesses 272. The vertical height of the second recess 272 may be less than the vertical height of the first recess 271. Therefore, the fourth sacrificial layer 280 formed on upper and lower surfaces of the second recess 272 may contact each other, so that the fourth sacrificial layer 280 may completely fill the second recess 272.

However, the fourth sacrificial layer 280 may be formed along surface profiles of the first hole 260 and the first recess 271, so that the fourth sacrificial layer 280 might not completely fill the first hole 260 and the first recess 271.

The fourth sacrificial layer 280 may include a material having a high etching selectivity with respect to the first sacrificial layers 222 and the second sacrificial layer pattern 224. In addition, the fourth sacrificial layer 280 may include a material having a high etching selectivity with respect to the first insulation layer 220.

The fourth sacrificial layer 280 may include a material different from that of the first sacrificial layers 222 and the second sacrificial layer pattern 224. The fourth sacrificial layer 280 may include a material different from that of the first insulation layer.

In some example embodiments of the present inventive concept, the fourth sacrificial layer 280 may include polysilicon. In some example embodiments of the present inventive concept, the fourth sacrificial layer 280 may include tungsten or aluminum oxide. Hereinafter, the fourth sacrificial layer 280 of polysilicon may be described. However, even though the fourth sacrificial layer 280 may be formed of a different material, the same subsequent processes may be performed.

Referring to FIG. 12, the fourth sacrificial layer 280 may be partially removed to form a fourth sacrificial layer pattern 280a in the second recess 272.

In the removing process, the fourth sacrificial layer 280 formed on the surfaces of the first holes 260 and inside of the first recess 271 may be removed. Accordingly, the sidewall of the third sacrificial layer pattern 274a may be exposed by the first recess 271. In addition, the fourth sacrificial layer 280 in the second recess 272 may be hardly removed or only partially removed to form the fourth sacrificial layer pattern 280a on the sidewall of the first sacrificial layer 222. The removing process may include, e.g., a wet etching process.

Since the fourth sacrificial layer 280 has a high etching selectivity with respect to the first insulation layer 220, the first insulation layer 220 might not be removed in the partially removing process of the fourth sacrificial layer 280. Since the first insulation layer 220 corresponding to the upper and lower surfaces of the first recess 271 may be hardly removed (or, e.g., not removed at all), the vertical height (i.e., vertical thickness) in the first recess 271 might not be increased.

If the fourth sacrificial layer 280 is formed of polysilicon and the oxide layer pattern 120 (see FIG. 10) is not formed on the protective pattern 109 (see FIG. 10), the protective pattern 109 exposed by the bottom of the first hole 260 may be partially removed or damaged during the partially removing process of the fourth sacrificial layer 280. However, since the oxide layer pattern 120 is formed on the protective pattern 109, the protective pattern 109 might not be removed or damaged during the partially removing process of the fourth sacrificial layer 280.

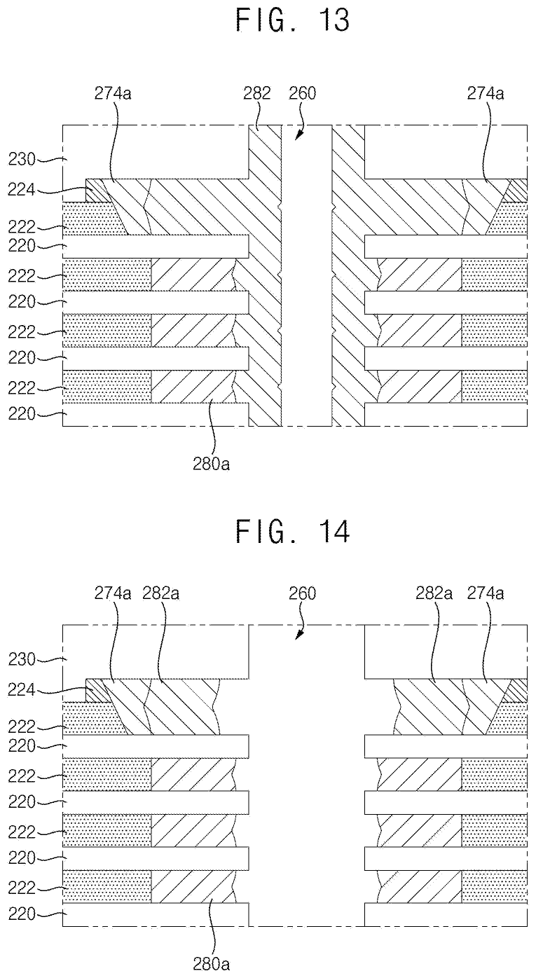

Referring to FIG. 13, a fifth sacrificial layer 282 may be conformally formed along the upper surface of the second insulating interlayer 254, the surfaces of the first holes 260, and the surfaces of the first and second recesses 271 and 272. The fifth sacrificial layer 282 may fill the first and second recesses 271 and 272. For example, the fifth sacrificial layer 282 may completely fill the first and second recesses 271 and 272. However, the fifth sacrificial layer 282 may be formed along surfaces of the first holes 260 without completely filling the first holes 260.

The fifth sacrificial layer 282 may include a material including elements the same as elements of the first sacrificial layer 222 and the second sacrificial layer pattern 224. The fifth sacrificial layer 282 may include, e.g., silicon nitride. In some example embodiments of the present inventive concept, the fifth sacrificial layer 282 may be formed by a low-pressure chemical vapor deposition process.

The fifth sacrificial layer 282 may include a material substantially the same as a material of the third sacrificial layer pattern 274a. For example, the fifth sacrificial layer 282 and the third sacrificial layer pattern 274a may be merged to each other, and may be regarded as one layer.

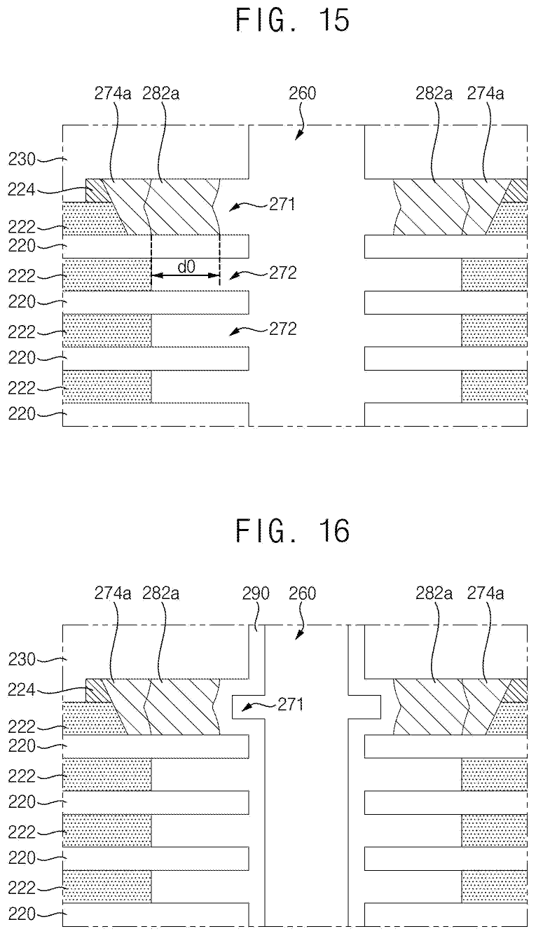

Referring to FIG. 14, the fifth sacrificial layer 282 may be partially removed to form a fifth sacrificial layer pattern 282a in the first recess 271.

In the removing process, the fifth sacrificial layer 282 that is formed on surfaces of the first holes 260 and inside the second recess 272 may be removed. Accordingly, the sidewall of the fourth sacrificial layer pattern 280a may be exposed by the second recess 272. In addition, the fifth sacrificial layer 282 in the first recess 271 may be partially removed to form the fifth sacrificial layer pattern 282a on the sidewall of the third sacrificial layer pattern 274a. The removing process may include, e.g., a wet etching process.

An etching process may be performed to expose the sidewall of the fourth sacrificial layer pattern 280a in the second recess 272. The fifth sacrificial layer 282 and the fourth sacrificial layer pattern 280a have a high etch selectivity to each other. When the fifth sacrificial layer 282 is partially removed, the fourth sacrificial layer pattern 280a may hardly be removed. In addition, the etching process may be easily stopped when the sidewall of the fourth sacrificial layer pattern 280a is completely exposed. Accordingly, an amount of the fifth sacrificial layer 282 removed from the first recess 271 may be minimized. Therefore, a horizontal width of the fifth sacrificial layer pattern 282a filling the first recess 271 may be increased. In addition, a distance between the sidewall of the fifth sacrificial layer pattern 282a in the first recess 271 and the sidewall of the first sacrificial layer 222 in the second recess 272 may be increased.

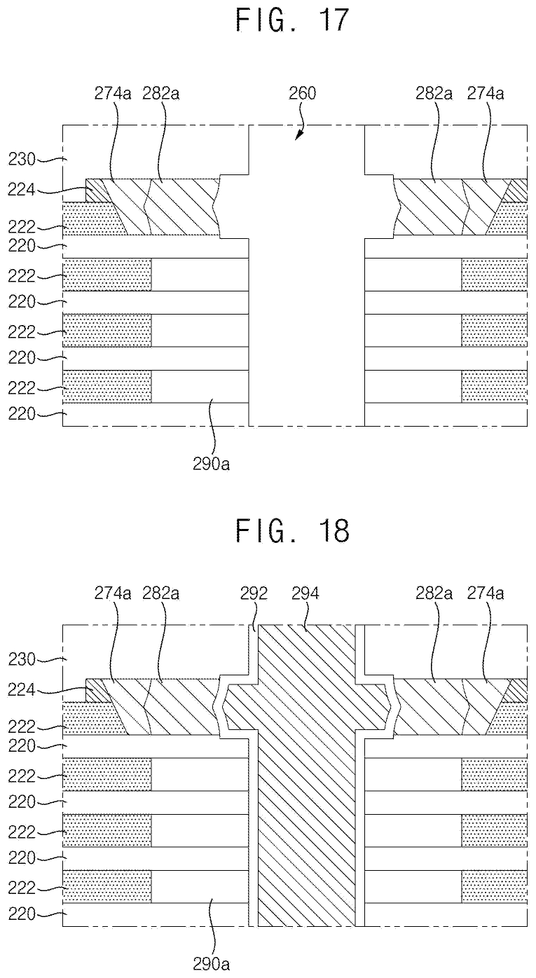

Referring to FIG. 15, the fourth sacrificial layer pattern 280a may be removed by e.g., a wet etching process.

In the removing process of the fourth sacrificial layer pattern 280a, the fifth sacrificial layer pattern 282a may hardly be removed.

Since the oxide layer pattern 120 is formed on the protective pattern 109, the protective pattern 109 might not be removed or damaged during the removing process of the fourth sacrificial layer pattern 280a.

According to the above process, the sidewall of the fifth sacrificial layer pattern 282a may be exposed by the first recess 271. In addition, the sidewall of the first sacrificial layer 222 may be exposed by the second recess 272. The sidewall of the fifth sacrificial layer pattern 282a in the first recess 271 may protrude from the sidewall of the first sacrificial layer 222 in the second recess 272 toward the first hole 260. For example, the fifth sacrificial layer pattern 282a may extend from a point of the sidewall of the first sacrificial layer 222 in the second recess toward the first hole 260. A distance from the sidewall of the first hole 260 to the sidewall of the fifth sacrificial layer pattern 282a in the first recess 271 may be less than a distance from the sidewall of the first hole 260 to the sidewall of the first sacrificial layer 222 in the second recess 272.

As the distance d0 between the sidewall of the fifth sacrificial layer pattern 282a in the first recess 271 and the sidewall of the first sacrificial layer 222 in the second recess 272 increases, a breakdown between a through cell contact and a gate pattern that are subsequently formed may be decreased. The distance d0 may be a predetermined distance so that the breakdown between the through cell contact and the gate pattern might not occur. In some example embodiments of the present inventive concept, the distance d0 between the sidewall of the fifth sacrificial layer pattern 282a in the first recess 271 and the sidewall of the first sacrificial layer 222 in the second recess 272 may be greater than about 15 nm.

Referring to FIG. 16, a second insulation layer 290 may be conformally formed along the upper surface of the second insulating interlayer 254, the surfaces of the first holes 260, and the surfaces of the first and second recesses 271 and 272. The second insulation layer 290 may be formed to fill the second recess 272. For example, the second insulation layer 290 may be formed to completely fill the second recess 272. Since the vertical height of the second recess 272 may be less than the vertical height of the first recess 271, the second insulation layers 290 formed on the upper and lower surfaces of the second recess 272 may contact each other to fill the second recess 272. Thus, the second insulation layer 290 may completely fill the second recess 272.

However, the second insulation layer 290 may be formed along surface profiles of the first hole 260 and the first recess 271 without completely filling the first holes 260 and the first recess 271.

The second insulation layer 290 may include a material having a high etching selectivity with respect to the first sacrificial layer 222 and the second sacrificial layer pattern 224. The second insulation layer 290 may include, e.g., silicon oxide.

Referring to FIG. 17, the second insulation layer 290 may be partially removed to form a second insulation pattern 290a in the second recess 272.

In the removing process, the second insulation layer 290 formed on the surface of the first holes 260 and inside the first recess 271 may be removed. Accordingly, the sidewall of the fifth sacrificial layer pattern 282a may be exposed by the first recess 271. In addition, the second insulation layer 290 in the second recess 272 may be hardly removed or only partially removed, so that the second insulation pattern 290a may be formed on the sidewall of the first sacrificial layer 222 in the second recess 272. The removing process may include, e.g., a wet etching process.

In the removing process of the second insulation layer 290, the first insulation layers 220 that are exposed by the upper and lower surfaces of the first recess 271 may also be partially removed. Accordingly, the vertical height of the first recess 271 adjacent to the sidewall of the fifth sacrificial layer pattern 282a may be increased. The vertical height of the first recess 271 adjacent to the sidewall of the fifth sacrificial layer pattern 282a may be greater than a vertical thickness of the fifth sacrificial layer pattern 282a. In addition, a vertical thickness of the first insulation layer 220 disposed under the first recess 271 may be less than a vertical thickness of the first insulation layer 220 disposed under a bottom surface of the fifth sacrificial layer pattern 282a.

Referring to FIG. 18, a liner layer including an insulation material may be conformally formed along the upper surface of the second insulating interlayer 254, the surfaces of the first holes 260, and the surface of the first recess 271. The liner layer may be formed along surface profiles of the first holes 260 and the first recess 271, and might not completely fill the first hole 260 and the first recess 271.

Thereafter, a sixth sacrificial layer may be formed on the liner layer to fill the first holes 260 and the first recess 271. For example, the sixth sacrificial layer may completely fill the first holes 260 and the first recess 271. The sixth sacrificial layer may include, e.g., polysilicon. The sixth sacrificial layer and the liner layer may be planarized until the upper surface of the second insulating interlayer 254 may be exposed to form an insulation liner 292 and a sixth sacrificial layer pattern 294. The insulation liner 292 and the sixth sacrificial layer pattern 294 may be formed in the first holes 260 and the first recess 271. A through cell contact may be formed in a region where the insulation liner 292 and the sixth sacrificial layer pattern 294 are formed by subsequent processes.

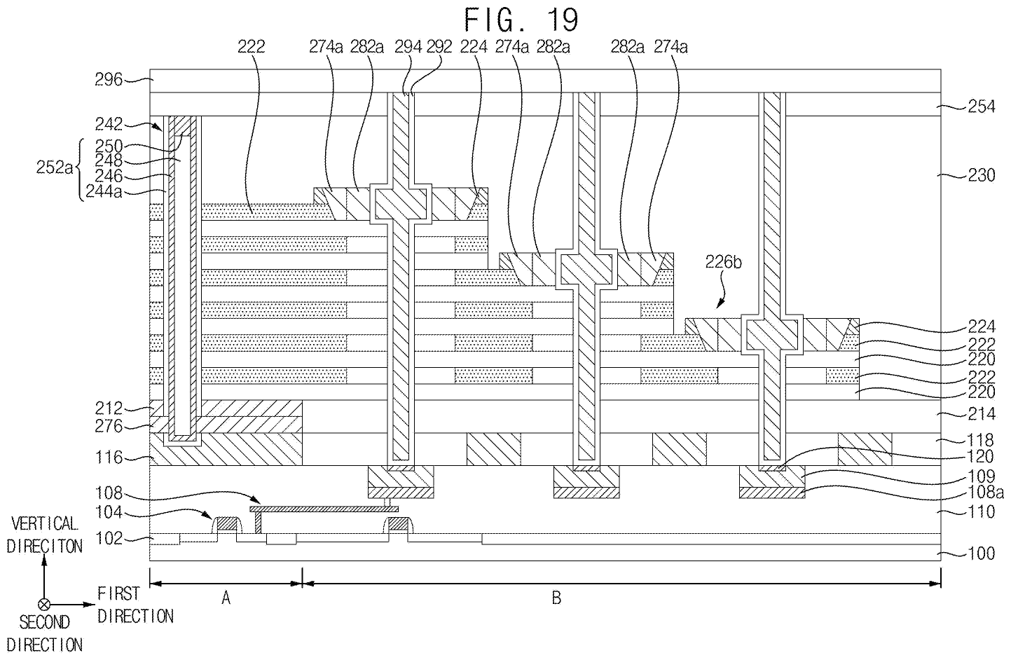

Referring to FIG. 19, a third insulating interlayer 296 may be formed on the second insulating interlayer 254, the insulation liner 292 and the sixth sacrificial layer pattern 294. An etching mask may be formed on the third insulating interlayer 296. The third insulating interlayer 296, the first and second insulating interlayers 230 and 254, the second preliminary mold structure 226a, the support layer pattern 212, the lower sacrificial layer structure 210, and the lower insulation layer pattern 214 may be etched using the etching mask to form a first opening extending in the first direction. By the etching process, the second preliminary mold structure 226a may be cut to form a mold structure 226b having a line shape.

The first opening may extend in the first direction from the first region A to the second region B. The first opening may serve as a word line cutting region.

Thereafter, a spacer may be formed on the sidewall of the first opening positioned higher than the support layer pattern 212. The lower sacrificial layer structure 210 may be selectively removed to form a first gap. Then, the preliminary charge storage structure 244 exposed by the first gap may be etched to form a charge storage structure 244a. A lower portion of the channel 246 may be exposed by the etching process. Accordingly, a channel structure 252a may be formed in the channel hole 242.

A channel connection pattern 276 may be formed to fill the first gap. Channels 246 formed in each channel hole 242 may be electrically connected to each other by the channel connection pattern 276. Channels 246 may be electrically connected to the base pattern 116 in the first region A by the channel connection pattern 276. The channel connection pattern 276 may include, e.g., polysilicon. The spacer may be removed.

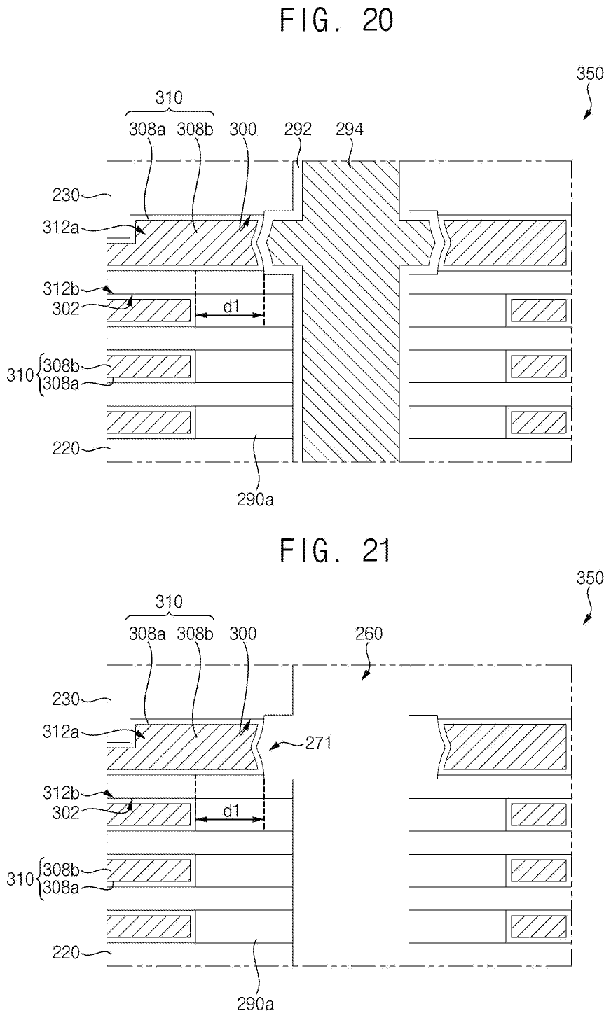

Referring to FIG. 20, the first sacrificial layer 222, the second sacrificial layer pattern 224, the third sacrificial layer pattern 274a and the fifth sacrificial layer pattern 282a exposed by the sidewall of the first opening may be removed to form a second gap 300 and a third gap 302. The removing process may include, e.g., a wet etching process.

The second gap 300 having a first height may be formed by etching of an uppermost step portion including the first sacrificial layer 222, the second sacrificial layer pattern 224, the third sacrificial layer pattern, and the fifth sacrificial layer pattern. The third gap 302 having a second height less than the first height may be formed by etching of a portion having only the first sacrificial layer 222.

Thereafter, a first barrier metal layer may be formed along surfaces of the second gap 300 and the third gap 302. A gate conductive layer may be formed on the first barrier metal layer to fill the second gap 300 and the third gap 302.

In some example embodiments of the present inventive concept, a second blocking layer may be formed before forming the first barrier metal layer. The second blocking layer may include aluminum oxide. The first barrier metal layer may include, e.g., titanium, titanium nitride, tantalum, and tantalum nitride. The gate conductive layer may include a metal material such as tungsten, copper, or aluminum.

Thereafter, portions of the first barrier metal layer and the gate conductive layer may be removed so that the first barrier metal layer and the gate conductive layer remain only inside the second gap 300 and the third gap 302. Thus, gate patterns may be formed in the second gap 300 and the third gap 302. The gate pattern 310 may include a first barrier metal pattern 308a and a first metal pattern 308b.

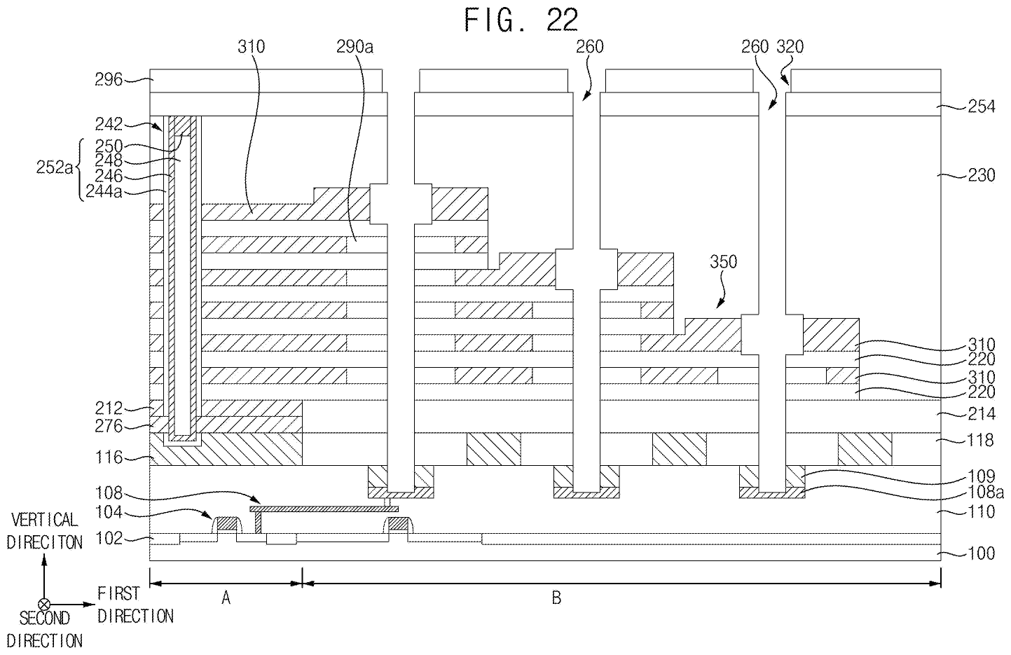

Therefore, a cell stack structure 350 (see FIG. 22) extending in the first direction and having a stepped shape at an edge in the first direction may be formed. The cell stack structure 350 may include the first insulation layer 220 and the gate pattern 310 that are alternately and repeatedly stacked.

In the cell stack structure 350, the gate pattern 310 positioned within the second gap 300 may be referred to as the gate pattern 312a of the first portion, and the gate pattern 310 positioned within the third gap 302 may be referred to as the gate pattern 312b of the second portion. The gate pattern 312a of the first portion may correspond to a stepped portion of the edge in the first direction. The gate pattern 312a of the first portion may correspond to an uppermost gate pattern disposed adjacent to the first hole 260. The gate pattern 312a of the first portion may have a first thickness in the vertical direction. In addition, the gate pattern 312b of a second portion positioned beside the step portion may have a second thickness less than the first thickness in the vertical direction.

In some example embodiments of the present inventive concept, at least one of the gate patterns 310 may include the gate pattern 312a of the second portion and the gate pattern 312a of the first portion connected to the gate pattern 312a of the second portion in the first direction. A vertical thickness of the gate pattern 312a of the second portion may be less than a vertical thickness of the gate pattern 312a of the first portion.

In the cross-sectional view, a sidewall of the gate pattern 312a of the first portion adjacent to the first hole 260 may protrude in a horizontal direction from a sidewall of the gate pattern 312a of the second portion adjacent to the first hole 260. The sidewall of the gate pattern 312a of the first portion adjacent to the first hole 260 may be closer to the first hole 260 rather than the sidewall of the gate pattern 312a of the second portion adjacent to the first hole 260.

In some example embodiments of the present inventive concept, at least a portion of a lower surface of the gate pattern 312a of the first portion may overlap the second insulation pattern 290a. A second insulation pattern 290a may be disposed below a lower surface of the gate pattern 312a of the first portion that is adjacent to the first hole 260.

In some example embodiments of the present inventive concept, in the cross-sectional view, a distance d1 in the horizontal direction (i.e., horizontal distance) between the sidewall of the gate pattern 312a of the first portion, which is adjacent to the first hole 260, and the sidewall of the gate pattern 312a of the second portion, which is positioned below the gate pattern 312a of the first portion, may be about 15 nm or more.

The distance d1 may be substantially the same as the distance d0 between the sidewall of the fifth sacrificial layer pattern 282a in the first recess 271 and the sidewall of the first sacrificial layer 222 in the second recess 272, in the process described with reference to FIG. 14,

Thereafter, an insulation layer may be formed in the first opening, and the insulation layer may be planarized to form a filling insulation pattern in the first opening. The filling insulation pattern may include silicon oxide.

Referring to FIGS. 21 and 22, a photoresist pattern may be formed to expose only a portion of the first hole 260. The third insulating interlayer 296 may be anisotropically etched using the photoresist pattern as an etching mask to form an upper opening 320. Thereafter, the sixth sacrificial layer pattern 294 and the insulation liner 292 in the first hole 260 may be selectively removed. The selective removing process may include, e.g., wet etching process.

When the etching process is performed, the gate pattern 310 may be exposed on the sidewall of the first recess 271.

In this case, the second insulation pattern 290a filling the second recess 272 may remain without being removed. Accordingly, the second insulation pattern 290a may be provided on the sidewall of the gate pattern 310 formed below the first recess 271, so that the sidewall of the gate pattern 310 might not be exposed.

Thereafter, the oxide layer pattern 120 and the protective pattern 109 on a bottom of the first hole 260 may be removed. Accordingly, the lower pad pattern 108a may be exposed by a bottom surface of the first hole 260.

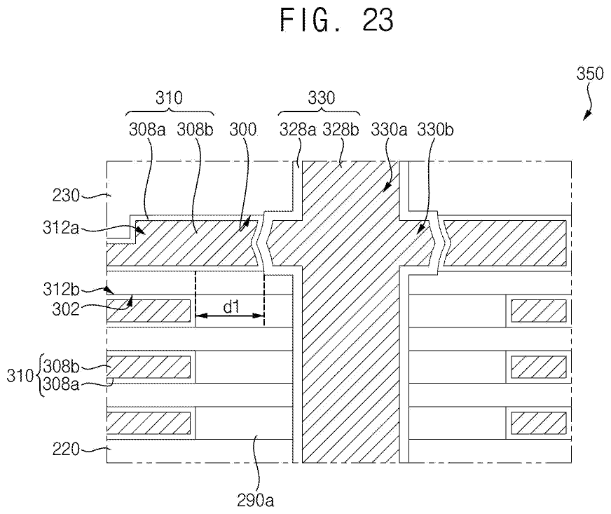

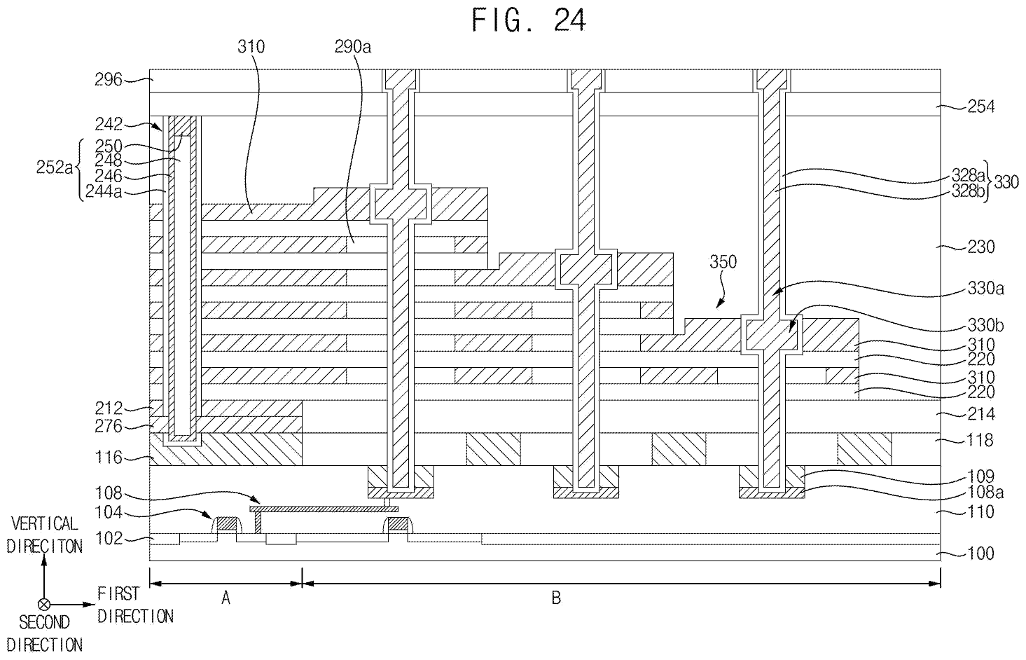

Referring to FIGS. 23 and 24, a conductive layer may be formed on the third insulating interlayer 296 to fill the upper opening 320, the first hole 260 and the first recess 271.

The conductive layer may include a second barrier metal layer and a metal layer. The second barrier metal layer may include, e.g., titanium, titanium nitride, tantalum, and tantalum nitride. The second metal layer may include a metal material such as tungsten, copper, or aluminum.

Thereafter, the conductive layer may be polished until the third insulating interlayer 296 is exposed to form a through cell contact 330. The through cell contact 330 may be formed in the upper opening 320, the first hole 260 and the first recess 271. The through cell contact 330 may include a second barrier metal layer pattern 328a and a second metal pattern 328b.

The through cell contact 330 may include a first through portion 330a passing through the cell stack structure 350 and a first protrusion 330b protruding from a sidewall of the first through portion 330a. An end of the first protrusion 330b may contact a sidewall of an uppermost gate pattern 310 that is adjacent to the first through portion 330a.

The vertical height of the first recess 271 for forming the first protrusion 330b may be greater than a vertical thickness of the gate pattern 312a of the first portion. Accordingly, a vertical thickness of the first protrusion 330b may be greater than the vertical thickness of the gate pattern 312a of the first portion.

As such, the vertical thickness of the first protrusion 330b may be increased, and in the cross-sectional view, the horizontal distance between the sidewall of the gate pattern 310 disposed below the first protrusion 330b (that is, the sidewall of gate pattern 310 adjacent to the through cell contact 330) and an end of the first protrusion 330b may be short. In this case, a defect between the uppermost gate pattern 310 and the gate pattern 310 disposed therebelow may occur. For example, a high voltage may be applied to the uppermost gate pattern 310 and a relatively low voltage may be applied to the gate pattern 310 below the uppermost gate pattern 310. Therefore, a breakdown due to a high voltage difference between the upper and lower gate patterns 310 may occur, and thus an insulation material between the gate patterns 310 may be physically damaged and leakage currents may be generated. However, in some example embodiments of the present inventive concept, a horizontal distance between the end of the first protrusion 330b and the sidewall of the gate pattern 310 disposed below the first protrusion 330b may be about 15 nm or more. As the horizontal distance is sufficiently increased to about 15 nm or more, defects between the uppermost gate pattern 310 and the gate pattern 310 therebelow might not occur even if the vertical thickness of the first protrusion 330b is increased.

The first protrusion 330b of the through cell contact 330 contacts the uppermost gate pattern 310, and thus the through cell contact 330 and the uppermost gate pattern 310 may be electrically connected to each other.

In the through cell contact 330, the first through portion 330a below the first protrusion 330b may be at least partially surrounded by the second insulation pattern 290a. The second insulation pattern 290a may have an annular shape. A bottom surface of the first protrusion 330b may face the second insulation pattern 290a. The second insulation pattern 290a may protrude from the sidewall of the first through portion 330a. The second insulation pattern 290a may be longer than the first protrusion 330b from the sidewall of the first through portion 330a.

As such, the through cell contact 330 may electrically connect one gate pattern 310 and the lower pad pattern 108a to each other, so that a wiring structure may simplified.

A vertical memory device may be manufactured by the above process.

The vertical memory device manufactured by the above process may have the following structural characteristics. Since most of the characteristics of the vertical memory device have been described, different characteristics may be described below.

The characteristics of the vertical memory device may be described with reference to FIGS. 23 and 24 again.

Referring to FIGS. 23 and 24 again, circuit patterns constituting a peripheral circuit may be formed on a substrate 100, and a lower insulating interlayer 110 may be formed to cover the circuit patterns.

The circuit patterns may include a lower transistor 104 and lower wirings 108. The lower wiring 108 may include a lower pad pattern 108a. A protective pattern 109 may be formed on the lower pad pattern 108a.

Abase pattern 116 and a base insulation layer 118 may be formed on the lower insulating interlayer 110.

The substrate 100 may include a first region A, where a memory cell array is formed, and a second region B that extends from the memory cell array.

A first insulation layer 220 and a gate pattern 310 may be alternately and repeatedly stacked on the base pattern 116 and the base insulation layer 118. The first insulation layers 220 and gate patterns 310 may form a cell stack structure 350. The cell stack structure 350 may extend in the first direction parallel to the upper surface of the substrate 100, and may have a stepped shape at an edge in the first direction. The gate pattern 310 may include, e.g., tungsten, and the first insulation layer 220 may include, e.g., silicon oxide.

The cell stack structure 350 may extend from the first region A to the second region B, and the cell stack structure on the second area B may have the stepped shape.

A step portion of the cell stack structure 350 may include a step having an exposed upper surface at an edge. A through cell contact 330 may be formed through the step portion of the cell stack structure 350 to be electrically connected to one of the gate patterns 310.

The uppermost gate pattern 310 contacting the through cell contact 330 may correspond to the gate pattern 312a of the first portion. Other gate pattern below the uppermost gate pattern 310 may correspond to the gate pattern 312b of the second portion. A vertical thickness (i.e., height) of the gate pattern 312a of the first portion may be greater than a vertical thickness of the gate pattern 312b of the second portion. For example, the vertical thickness of the uppermost gate pattern 312a contacting the first protrusion 330b of the through cell contact 330 may be greater than the vertical thickness of the gate pattern 312b there below.

A first insulating interlayer 230, a second insulating interlayer 254 and a third insulating interlayer 296 may cover the cell stack structure 350.

The through cell contact 330 may extend in the vertical direction from the third insulating interlayer 296 so as to pass through the gate pattern 312a of the first portion in the cell stack structure 350. The through cell contact 330 may be electrically connected with a sidewall of an uppermost gate pattern 312a and the lower pad pattern 108a. The through cell contact 330 may pass through the first to third insulating interlayers 230, 254 and 296, the lower insulation layer pattern 214, the base insulation layer 118 and the protective pattern 109. A bottom surface of the through cell contact 330 may contact an upper surface of the lower pad pattern 108a.

The through cell contact 330 may have a first through portion 330a and a first protrusion 330b. The first through portion 330a may extend in the vertical direction from the third insulating interlayer 296 to the lower pad pattern 108a, and may pass through the gate pattern 312a of the first portion in the cell stack structure 350. The first protrusion 330b may contact the uppermost gate pattern 310 that is adjacent to the first through portion 330a.

An end of the first protrusion 330b may contact a sidewall of an uppermost gate pattern 310 adjacent to the first through portion 330a. The through cell contact 330 may include a second barrier metal layer pattern 328a and a second metal pattern 328b. The second barrier metal layer pattern 328a may include, e.g., titanium, titanium nitride, tantalum, or tantalum nitride. The second metal pattern 328b may include a metal material such as tungsten, copper, or aluminum. For example, the second metal pattern 328b may include tungsten.

The first protrusion 330b may have an annular shape surrounding the first through portion 330a.

The vertical thickness of the first protrusion 330b may be greater than the vertical thickness (i.e., height) of the gate pattern 312a of the first portion. The vertical thickness of the first protrusion 330b may be greater than the vertical thickness of the uppermost gate pattern 310 contacting the first protrusion 330b.

In some example embodiments of the present inventive concept, at a contacting portion between the first protrusion 330b and the gate pattern 312a of the first portion, the first protrusion 330b may protrude from each of an upper surface and a lower surface of the gate pattern 312a of the first portion. For example, the first protrusion 330b may have a vertical thickness greater than that of the gate pattern 312a.

In some example embodiments of the present inventive concept, a length of the first protrusion 330b in the horizontal direction may be substantially the same as or smaller than a horizontal distance between a contacting portion, which is between the first protrusion 330b and the uppermost gate pattern 310, and a contacting portion, which is between the second insulation pattern 290a and the gate pattern 310.

In the cross-sectional view taken in the first direction, the uppermost gate pattern 310 contacting the through cell contact 330 may protrude from the gate pattern 310 therebelow, toward the through cell contact 330 in the horizontal direction.

A second insulation pattern 290a may surround a sidewall of the first through portion 330a below the first protrusion 330b. The second insulation pattern 290a may extend from the first through portion 330a, and the second insulation pattern 290a may be longer than the first protrusion 330b in a horizontal direction from the first through portion 330a. The second insulation pattern 290a may include, e.g., silicon oxide. A sidewall of the second insulation pattern 290a may contact a sidewall of a gate pattern 310 that is below the uppermost gate pattern 310.

At least a portion of a bottom surface of the uppermost gate pattern 310, that is contacting the through cell contact 330, may face the second insulation pattern 290a.

As the horizontal distance between an end of the first protrusion 330b, which contacts the uppermost gate pattern 310, and a sidewall of the gate pattern 310, which contacts the second insulation pattern 290a below the uppermost gate pattern 310, is increased, defects between a through cell contact 330 and the gate pattern 310 may be prevented. For example, defects between the through cell contact 330 and the gate pattern 310, which is below the uppermost gate pattern 310, may be prevented.

In some example embodiments of the present inventive concept, the horizontal distance between the end of the first protrusion 330b, which contacts the uppermost gate pattern 310, and the gate pattern 310, which contacts the second insulation pattern 290a below the uppermost gate pattern 310, may be about 15 nm or more.

In the cross-sectional view, a horizontal distance from the outer wall of the first through portion 330a to a side surface of the first protrusion 330b may be less than a horizontal distance from the outer wall of the first through portion 330a to a side surface of the second insulation pattern 290a. For example, a length in the horizontal direction of the first protrusion 330b may be less than a length in the horizontal direction of the second insulation pattern 290a protruding from the first through portion 330a.

A vertical thickness of the first protrusion 330b may be greater than a vertical thickness of the second insulation pattern 290a, which surrounds the first through portion 330a.

As such, the sidewall of the end of the first protrusion 330b of the through cell contact 330 may contact the uppermost gate pattern 310, and the other sidewall of the through cell contact 330 may contact the insulation material. Accordingly, the through cell contact 330 may be only electrically connected to the uppermost gate pattern 310 that is adjacent to the first through portion 330a, and may be electrically insulated from the gate patterns 310 positioned below the uppermost gate pattern 310.

In addition, channel structures 252a may pass through the cell stack structure 350 in the first region A of the substrate 100.

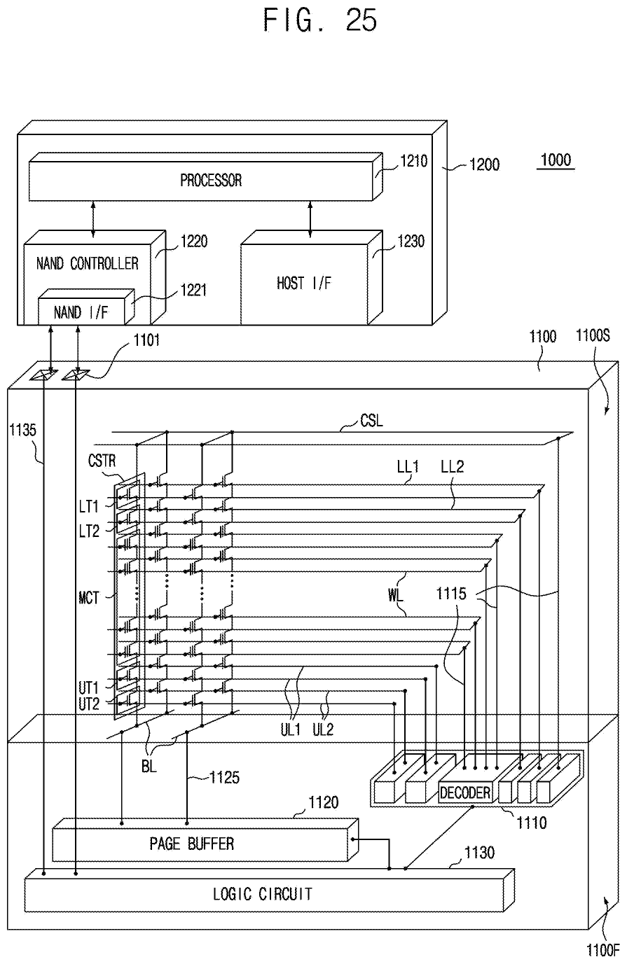

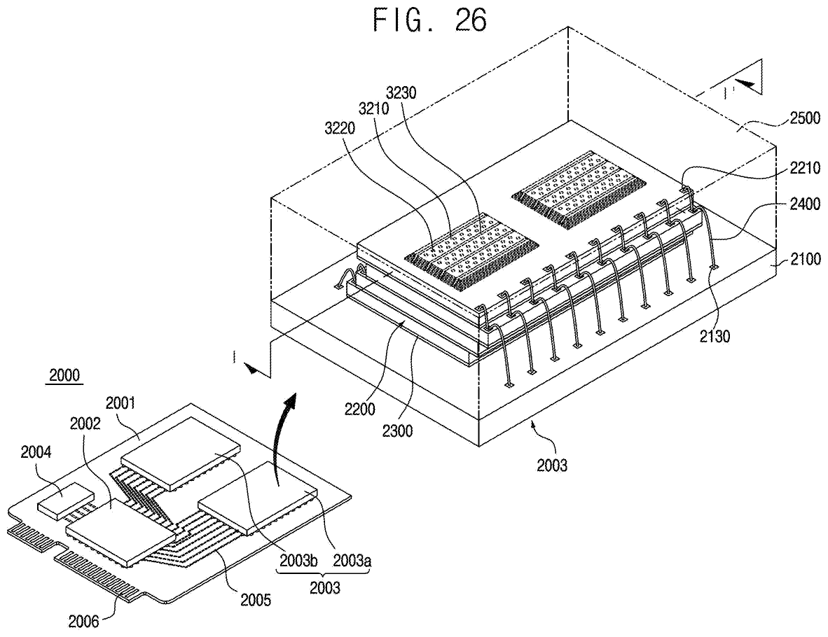

FIG. 25 is a schematic diagram illustrating an electronic system including a semiconductor device according to an example embodiment of the present inventive concept.

Referring to FIG. 25, an electronic system 1000 may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device 1100, a universal serial bus (USB), a computing system, a medical device, or a communication device including one or a plurality of semiconductor devices 1100.

The semiconductor device 1100 may be a non-volatile memory device. For example, the semiconductor device 1100 may be the vertical memory device shown in FIGS. 23 and 24. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may include a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT that disposed between the lower transistors LT1 and LT2 and the upper transistors UT1 and UT2. The number of lower transistors LT1 and LT2 and the number of upper transistors UT1 and UT2 may be variously modified according to example embodiments of the present inventive concept.

In some example embodiments of the present inventive concept, the upper transistors UT1 and UT2 may include string select transistors, and the lower transistors LT1 and LT2 may include ground select transistors. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In some example embodiments of the present inventive concept, the lower transistors LT1 and LT2 may include a lower erase control transistor LT1 and a ground selection transistor LT2 connected in series to each other. The upper transistors UT1 and UT2 may include a string select transistor UT1 and an upper erase control transistor UT2 connected in series to each other. At least one of the lower erase control transistor LT1 and/or the upper erase control transistor UT1 performs an erase operation of data stored in the memory cell transistors MCT using a gate induce drain leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection wirings 1115 extending from the first structure 1100F to the second structure 1100S. The bit lines BL may be electrically connected to the page buffer 1120 through second connection wirings 1125 extending from the first structure 1100F to the second structure 1100S.

In the first structure 1100F, the decoder circuit 1110 and the page buffer 1120 may control at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 extending from the first structure 1100F to the second structure 1100S.

The controller 1200 may include a processor 1210, a NAND controller 1220, and a host interface 1230. In some example embodiments of the present inventive concept, the electronic system 1000 may include a plurality of semiconductor devices 1100, and in this case, the controller 1200 may control the plurality of semiconductor devices 1100.

The processor 1210 may control overall operations of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. Through the NAND interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may enable communication between the electronic system 1000 and an external host. When the control command is received from the external host through the host interface 1230, the processor 1210 may control the semiconductor device 1100 in response to the control command.

FIG. 26 is a schematic perspective view of an electronic system including a semiconductor device according to an example embodiment of the present inventive concept.

Referring to FIG. 26, an electronic system 2000 may include a main board 2001, a controller 2002 mounted on the main board 2001, one or more semiconductor packages 2003, and a dynamic random access memory (DRAM) device 2004. The semiconductor package 2003 and the DRAM device 2004 may be connected to the controller 2002 through wiring patterns 2005 that are formed on the main board 2001.

The main board 2001 may include a connector 2006 including a plurality of pins coupled to an external host. The number and arrangement of the plurality of pins in the connector 2006 may vary depending on the communication interface between the electronic system 2000 and the external host. In some example embodiments of the present inventive concept, the electronic system 2000 may communicate with the external host by any one of interfaces including, e.g., USB, Peripheral Component Interconnect Express (PCI-Express), Serial Advanced Technology Attachment (SATA), and M-Phy for Universal Flash Storage (UFS). In some example embodiments of the present inventive concept, the electronic system 2000 may operate by power supplied from an external host through the connector 2006. The electronic system 2000 may further include a Power Management Integrated Circuit (PMIC) that distributes power supplied from the external host to the controller 2002 and the semiconductor package 2003.

The controller 2002 may write data to the semiconductor package 2003 or read data from the semiconductor package 2003, and may increase the operating speed of the electronic system 2000.

The DRAM device 2004 may be a buffer memory for reducing a difference between a speed of the semiconductor package 2003 for storing data and a speed of the external host. The DRAM device 2004 included in the electronic system 2000 may also operate as a kind of a cache memory, and may provide a space for temporarily storing data in a control operation of the semiconductor package 2003. When the DRAM 2004 is included in the electronic system 2000, the controller 2002 may include a DRAM controller for controlling the DRAM device 2004 and a NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, and adhesive layers 2300 disposed on a lower surface of each of the semiconductor chips 2200, a connection structure 2400 electrically connecting the semiconductor chips 2200 and the package substrate 2100 to each other, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 25. Each of the semiconductor chips 2200 may include gate electrode structures 3210, memory channel structures 3220 passing through each of the gate electrode structures 3210, and separation structures 3230 separating the gate electrode structures 3210. Each of the semiconductor chips 2200 may be, e.g., the vertical memory device shown in FIGS. 23 and 24.

In some example embodiments of the present inventive concept, the connection structure 2400 may be a bonding wiring electrically connecting the input/output pad 2210 and the package upper pads 2130. Accordingly, in each of the first and second semiconductor packages 2003a and 2003b, the semiconductor chips 2200 may be electrically connected to each other using a bonding wiring process, and the semiconductor chips 2200 may be electrically connected the package upper pads 2130 of the package substrate 2100. In addition, in each of the first and second semiconductor packages 2003a and 2003b, the semiconductor chips 2200 may be electrically connected to each other by through silicon vias (TSVs) instead of the wire bonding.

In some example embodiments of the present inventive concept, the controller 2002 and the semiconductor chips 2200 may be included in one package. In some example embodiments of the present inventive concept, the controller 2002 and the semiconductor chips 2200 may be mounted on a separate interposer substrate that is different from the main board 2001, and the controller 2002 and the semiconductor chips 2200 may be connected to each other by wirings formed on the interposer substrate.

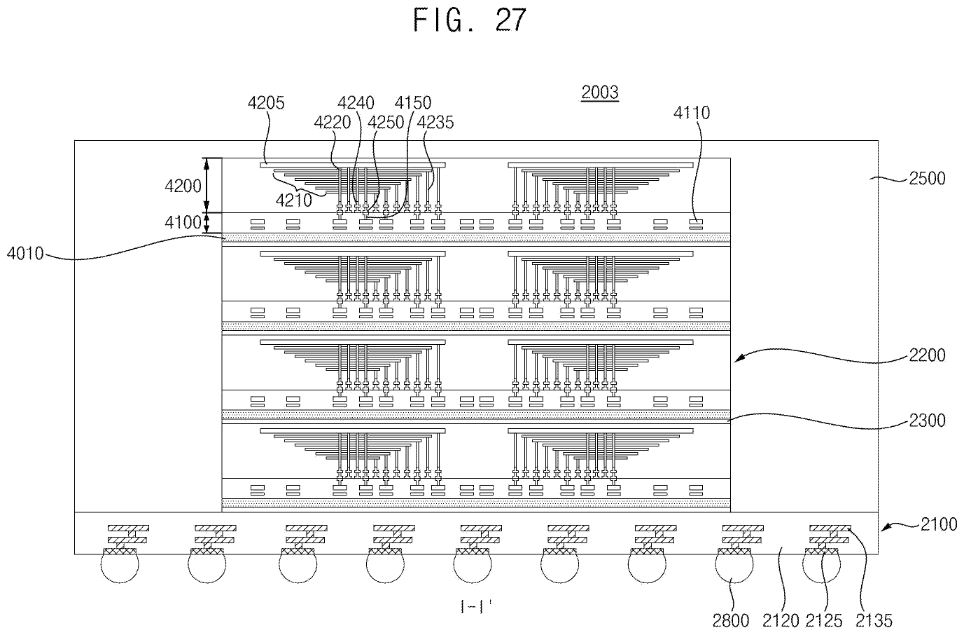

FIG. 27 is a schematic cross-sectional view illustrating a semiconductor package including a semiconductor device according to an example embodiment of the present inventive concept. FIG. 27 describes an example embodiment of the semiconductor package 2003 shown in FIG. 26, and shows a region obtained by cutting the semiconductor package 2003 of FIG. 26 along the cutting line I-I′.

Referring to FIG. 27, in the semiconductor package 2003, the package substrate 2100 may be a printed circuit board. The package substrate 2100 may include a package substrate body 2120, package upper pads 2130 (see FIG. 26) disposed on an upper surface of the package substrate body 2120, lower pads 2125 disposed on the lower surface of the package substrate body 2120 or exposed by the lower surface of the package substrate body 2120, and internal wirings 2135 electrically connecting the upper pads 2130 and the lower pads 2125 to each other and disposed inside the package substrate body 2120. The upper pads 2130 may be electrically connected to the connection structures 2400. The lower pads 2125 may be connected to the wiring patterns 2005 of the main board 2001 of the electronic system 2000 through the conductive connection portions 2800 as shown in FIG. 26.

Each of the semiconductor chips 2200 may include a semiconductor substrate 4010, a first structure 4100 on the semiconductor substrate 4010, and a second structure 4200 disposed on and bonded to the first structure 4100. The second structure 4200 may be bonded to the first structure 4100 by a wafer bonding process.

The first structure 4100 may include a peripheral circuit region in which the peripheral circuit wiring 4110 and a first bonding structure 4150 are formed. The second structure 4200 may include a common source line 4205, a gate electrode structure 4210 between the common source line 4205 and the first structure 4100, and memory channel structures 4220 and a separation structure 3230 (see FIG. 26) penetrating the gate electrode structure 4210, and the second boding structure 4250 electrically connected to the memory channel structures 4220 and the word lines (WL, see FIG. 25) of the gate electrode structure 4210. For example, the second bonding structure 4250 may be connected to bit lines 4240 that are electrically connected to memory channel structures 4220 and gates electrically connected to word lines WL (see FIG. 25). Each of the memory channel structures 4220 and the word lines WL (see FIG. 25) may be electrically connected to each other through the wirings 4235. The first bonding structures 4150 of the first structure 4100 and the second bonding structures 4250 of the second structure 4200 may be bonded to each other. A bonding portion between the first boding structures 4150 and the second bonding structures 4250 may be formed of, e.g., copper (Cu).

Each of the semiconductor chips 2200 may further include the input/output pads 2210 (see FIG. 26) electrically connected to the peripheral circuit wirings 4110 of the first structure 4100.

The semiconductor chips 2200 of FIG. 27 may be electrically connected to each other by the connection structures 2400 having bonding wiring. However, in some example embodiments of the present inventive concept, semiconductor chips in one semiconductor package, such as the semiconductor chips 2200 of FIG. 27, may be electrically connected to each other by a connection structure including the through silicon vias (TSVs).

While the present inventive concept has been described with reference to example embodiments thereof, it will be understood by those of ordinary skill in the art that various changes in form and details may be made thereto without departing from the spirit and scope of the present inventive concept.

What is claimed is:

1. A vertical memory device, comprising:
a lower pad pattern disposed on a substrate;
a cell stack structure disposed on the lower pad pattern, wherein the cell stack structure includes first insulation layers and gate patterns alternately and repeatedly stacked, wherein the cell stack structure extends in a first direction parallel to an upper surface of the substrate, and has a stepped shape;
a through cell contact including a first through portion and a first protrusion, wherein the first through portion extends in a vertical direction and passes through a portion of the cell stack structure having the stepped shape, and wherein the first protrusion protrudes from the first through portion and contacts a sidewall of an uppermost gate pattern, of the gate patterns, that is adjacent to the first through portion; and
a first insulation pattern at least partially surrounding a sidewall, of the first through portion, that is positioned below the first protrusion,
wherein the first insulation pattern is longer than the first protrusion in a horizontal direction from the first through portion, and
wherein a vertical thickness of the first protrusion of the through cell contact is greater than a vertical thickness of the uppermost gate pattern that contacts the first protrusion.

2. The vertical memory device of claim 1, wherein the first insulation pattern contacts a sidewall of a gate pattern, of the gate patterns, that is disposed below the uppermost gate pattern.

3. The vertical memory device of claim 1, wherein the vertical thickness of the uppermost gate pattern that contacts the first protrusion is greater than a vertical thickness of a gate pattern, of the gate patterns, disposed below the uppermost gate pattern.

4. The vertical memory device of claim 1, wherein a horizontal distance between a contacting portion that is between the first protrusion and the uppermost gate pattern and a contacting portion that is between the first insulation pattern and a gate pattern, of the gate patterns, disposed below the uppermost gate pattern is about 15 nm or more.

5. The vertical memory device of claim 1, wherein the first protrusion of the through cell contact has annular shape surrounding the first through portion.

6. The vertical memory device of claim 1, wherein at least a portion of a bottom surface of the uppermost gate pattern that contacts the through cell contact faces the first insulation pattern.

7. The vertical memory device of claim 1, wherein an end of the first protrusion of the through cell contact contacts the uppermost gate pattern, and a sidewall of the through cell contact contacts an insulation material.

8. The vertical memory device of claim 1, wherein the first protrusion of the through cell contact protrudes beyond upper and lower surfaces of the uppermost gate pattern that contacts the first protrusion.

9. The vertical memory device of claim 1, wherein a bottom surface of the through cell contact contacts the lower pad pattern.

10. A vertical memory device, comprising:
lower circuit patterns disposed on a substrate;
a lower pad pattern electrically connected to the lower circuit patterns;
a base pattern disposed on the lower pad pattern;
a cell stack structure disposed on the base pattern, wherein the cell stack structure includes first insulation layers and gate patterns alternately and repeatedly stacked, wherein the cell stack structure extends in a first direction parallel to an upper surface of the substrate, and having a stepped shape;
a channel structure extending to the base pattern and passing through the cell stack structure;
an insulating interlayer covering the cell stack structure;
a through cell contact including a first through portion and a first protrusion, wherein the first through portion extends in a vertical direction to the lower pad pattern and passes through the insulating interlayer and a portion having the stepped shape in the cell stack structure, and wherein the first protrusion protrudes from the first through portion and contacts a sidewall of an uppermost gate pattern, of the gate patterns, that is adjacent to the first through portion; and
a first insulation pattern at least partially surrounding a sidewall, of the first through portion, that is positioned below the first protrusion,
wherein the first insulation pattern has a length in the first direction that is greater than a length, in the first direction, of the first protrusion from the first through portion, and
wherein a horizontal distance between a contacting portion that is between the first protrusion and the uppermost gate pattern and a contacting portion that is between the first insulation pattern and a gate pattern, of the gate patterns, that is disposed below the uppermost gate pattern is about 15 nm or more.

11. The vertical memory device of claim 10, wherein a vertical thickness of the first protrusion of the through cell contact is greater than a vertical thickness of the uppermost gate pattern that contacts the first protrusion.

12. The vertical memory device of claim 10, wherein the first insulation pattern contacts a sidewall of the gate pattern that is disposed below the uppermost gate pattern.

13. The vertical memory device of claim 10, wherein a vertical thickness of an uppermost gate pattern that contacts the first protrusion is greater than a vertical thickness of the gate pattern that is disposed below the uppermost gate pattern.

14. The vertical memory device of claim 10, wherein the first protrusion of the through cell contact protrudes beyond upper and lower surfaces of the uppermost gate pattern that contacts the first protrusion.

15. The vertical memory device of claim 10, further comprising a protective pattern disposed on the lower pad pattern, and
wherein the through cell contact passes through the protective pattern.

16. The vertical memory device of claim 10, wherein the gate patterns include a metal, and the through cell contact includes a metal.

17. The vertical memory device of claim 10, wherein an end of the first protrusion of the through cell contact contacts the uppermost gate pattern, and a sidewall of the through cell contact contacts an insulation material.

18. A vertical memory device, comprising:
a cell stack structure disposed on a substrate, wherein the cell stack structure includes first insulation layers and gate patterns alternately and repeatedly stacked, wherein the cell stack structure has a stepped shape at an edge thereof, and wherein a thickness of an uppermost gate pattern, of the gate patterns, that is exposed at the edge is greater than that of the gate pattern, of the gate patterns, that is disposed below the uppermost gate pattern;
a through cell contact including a first through portion and a first protrusion, wherein the first through portion extends in a vertical direction and passes through the cell stack structure, and wherein the first protrusion protrudes from the first through portion and contacts a sidewall of the uppermost gate pattern that is adjacent to the first through portion; and
a first insulation pattern at least partially surrounding a sidewall, of the first through portion, that is positioned below the first protrusion, wherein the first insulation pattern contacts a sidewall of the gate pattern that is disposed below the uppermost gate pattern, and
wherein a horizontal distance between a contacting portion that is between the first protrusion and the uppermost gate pattern and a contacting portion that is between the first insulation pattern and the gate pattern that is disposed below the uppermost gate pattern is about 15 nm or more.

19. The vertical memory device of claim 18, wherein a vertical thickness of the first protrusion of the through cell contact is greater than the vertical thickness of the uppermost gate pattern that contacts the first protrusion.

20. The vertical memory device of claim 18, wherein a length of the first protrusion in a horizontal direction is a same as or less than the horizontal distance between the contacting portion that is between the first protrusion and the uppermost gate pattern and the contacting portion that is between the first insulation pattern and the gate pattern that is disposed below the uppermost gate pattern.
